(19) United States
(12) Patent Application Publication
(10) Pub. No.: US 2025/0382702 A1
(43) Pub. Date: Dec. 18, 2025

(54) LAMINATE FOR CHAMBER INNER WALL OF SEMICONDUCTOR MANUFACTURING APPARATUS

(71) Applicant: SAMSUNG ELECTRONICS CO., LTD., Suwon-si (KR)

(72) Inventors: CHANGHWAN KIM, Suwon-si (KR); Eunsook PARK, Suwon-si (KR); Takafumi NOGUCHI, Yokohama-shi (JP); Toshihiro IIZUKA, Yokohama-shi (JP); Kenichi NAGAYAMA, Yokohama-shi (JP)

(73) Assignee: SAMSUNG ELECTRONICS CO., LTD., Suwon-si (KR)

(21) Appl. No.: 19/227,059

(22) Filed: Jun. 3, 2025

(30) Foreign Application Priority Data
Jun. 18, 2024 (JP) 2024-097999

(51) Int. Cl. C23C 16/44

(52) U.S. Cl. CPC C23C 16/4404

(57) ABSTRACT

A laminate for a chamber inner wall of a semiconductor manufacturing apparatus is provided. The laminate prevents layer unevenness from occurring in the chamber inner wall. The laminate has a base material, an amorphous layer on the base material, and a crystalline layer on the amorphous layer. The thickness of the amorphous layer is greater than or equal to 1 nm and less than or equal to 10 nm. The crystalline layer includes yttrium and fluorine, and a density of the crystalline layer is greater than and equal to 4.7 g/cm³ and less than or equal to 5.3 g/cm³.

### CROSS-REFERENCE TO RELATED APPLICATIONS

This U.S. non-provisional patent application is based on and claims priority under 35 U.S.C. § 119 to Japanese Application No. 2024-097999, filed on Jun. 18, 2024, in the Japan Patent Office, the entire contents of which are hereby incorporated by reference.

### BACKGROUND

Embodiments of the present disclosure relate to a laminate for a chamber inner wall of a semiconductor manufacturing apparatus and a manufacturing method thereof.

The inside of a semiconductor manufacturing apparatus may be corroded by a manufacturing process using a corrosive gas, and dust and metal contamination may occur therein. In particular, internal parts made of aluminum alloys may be easily corroded by halogen gases such as fluorine.

Dust and metal contamination may cause yield reduction in semiconductor products. Therefore, conventionally, a corrosion-resistant coating layer such as an aluminum oxide (Al₂O₃) layer or an yttrium oxide (Y₂O₃) layer is formed on the inner wall of a chamber of a semiconductor manufacturing apparatus by using a method such as thermal spraying, a physical vapor deposition method (PVD), an aerosol deposition method (AD), or an atomic layer deposition method (ALD). In particular, it is desired to form a layer having high corrosion resistance by using ALD capable of forming a conformal dense layer.

With the miniaturization of state-of-the-art semiconductor devices, a solution to dust and metal contamination is required. An Al₂O₃ layer or a Y₂O₃ layer obtained by conventional thermal spraying has a problem of insufficient corrosion resistance. Therefore, a technique of using a YOF material for a coating layer has been proposed (see, for example, Patent Document 1). In addition, a technique using an oxygen-free YF₃ layer has been proposed (see, for example, Patent Document 2).
Patent Document 1: Japanese Published Patent Application No. 2023-014880
Patent Document 2: Japanese Published PCT Patent Application No. 2022-510278

However, when the YF₃ layer is formed using ALD, the vapor pressure of the yttrium-comprising source material is low, and thus it is difficult to form the layer. For example, the vapor pressure of a commercially available yttrium-comprising source material is three or more orders of magnitude lower than that of trimethylaluminum (TMA) used for forming an Al₂O₃ layer (see FIG. 1). Therefore, it is difficult to form a conformal YF₃ layer having a uniform thickness because the supply of the yttrium-comprising source material is insufficient.

In addition, fluorine used for the formation of the YF₃ layer corrodes the Al alloy, and a difference occurs in surface adsorption efficiency of a source material comprising yttrium due to poor surface conditions such as a crystal direction and a grain size of the YF₃ layer, so that it is difficult to form the YF₃ layer without occurrence of layer irregularity or unevenness.

### SUMMARY

Embodiments of the present disclosure may provide a method for forming a YF₃ layer in which layer irregularity does not occur on an inner wall of a chamber of a semiconductor manufacturing apparatus.

Embodiments of the present disclosure may provide a laminate for a chamber inner wall of a semiconductor manufacturing apparatus. The laminate may include a base material, an amorphous layer provided on the base material, and a crystalline layer provided on the amorphous layer.

In some example embodiments, the thickness of the amorphous layer may be greater than or equal to 1 nm and less than or equal to 10 nm.

In some example embodiments, the crystalline layer may include yttrium and fluorine.

In some example embodiments, the density of the crystalline layer may be 4.7 g/cm³ or more and 5.3 g/cm³ or less.

Embodiments of the present disclosure may provide a method for forming a laminate, wherein the method includes forming the crystalline layer on the surface of the amorphous layer by an atomic layer deposition method, wherein the forming of the crystalline layer may include supplying a first source material comprising yttrium and a second source material comprising fluorine, and the supply amount of the first source material may be adjusted so that the number of yttrium atoms supplied is 1.0×10¹⁵/cm³·cycle or more.

Embodiments of the present disclosure may provide a method for forming a laminate, wherein the method includes forming the crystalline layer on the surface of the amorphous layer by an atomic layer deposition method, wherein the forming of the crystalline layer includes supplying a first source material comprising yttrium and fluorine and a second source material comprising oxygen, and the supply amount of the first source material can be adjusted so that the number of yttrium atoms supplied is 1.0×10¹⁵/cm³·cycle or more.

In embodiments of the aforementioned methods, the number of yttrium atoms supplied is 1.0×10¹⁵/cm³·cycle or more and 1.0×10¹⁶/cm³·cycle or less.

In embodiments of the aforementioned methods, the number of yttrium atoms supplied is 1.0×10¹⁵/cm³·cycle or more and 5.5×10¹⁵/cm³·cycle or less.

In embodiments of the aforementioned methods, the atomic layer deposition method is plasma enhanced atomic layer deposition.

### BRIEF DESCRIPTION OF DRAWINGS

FIG. 1 is a graph showing the relationship between vapor pressure and temperature of trimethylaluminum (TMA), Ybeta-prime, tris (methylcyclopentadienyl) yttrium (Y (MeCp)₃), and tris (isopropylcyclopentadienyl) yttrium (Y (i-PrCp)₃).

FIG. 2 is a schematic diagram of a laminate according to embodiments of the present disclosure.

FIG. 3 is a schematic view of an SEM image of the laminate of Comparative Example 1.

FIG. 4 is a graph showing an X-ray diffraction pattern of the laminate of Example 1.

FIG. 5 is a graph showing the X-ray diffraction patterns of the crystalline layer (YF₃ layer) of the laminate of Example 9 and the amorphous layer (YF₃ layer) of Comparative Example 2.

FIG. 6 shows the results of visual evaluation of the laminates of Examples 2, 4, 6, and 8 and Comparative Example 1.

FIG. 7 shows evaluation results of layer peeling and layer cracking of the laminates of Examples 1 and 7 and Comparative Examples 3 and 4.

FIG. 8 shows evaluation results of layer peeling and layer cracking of the laminates of Examples 1, 3, 5, and 7 and Comparative Example 3.

FIG. 9 shows evaluation results of layer peeling and layer cracking of the laminates of Examples 2, 4, 6, and 8.

FIG. 10 is a graph showing the relationship between the etching depth normalized by Al₂O₃ and the layer density with respect to the crystalline layer (YF₃ layer) of the laminates of Examples 1 to 9 and Comparative Example 1 and the amorphous layer (YF₃ layer and Al₂O₃ layer) of the laminates of Comparative Examples 2 and 4.

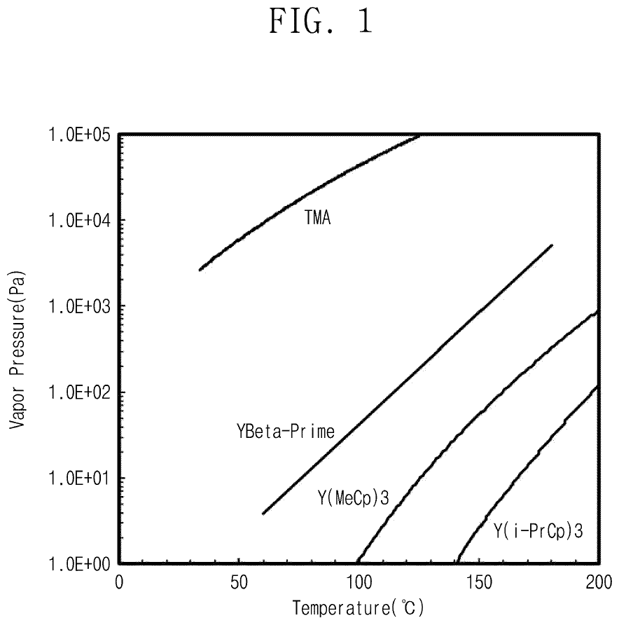

### DETAILED DESCRIPTION

Example embodiments of the present disclosure will now be described more fully with reference to the accompanying drawings, in which example embodiments are shown.

Hereinafter, embodiments of the present disclosure will be described in detail, but the present disclosure are not limited to the following embodiments and can be variously modified within the scope of the claims. The embodiments described herein may be modified by combination of described embodiments. In the specification, unless otherwise specified, operation and measurement of physical properties are performed under conditions of room temperature (20° C. or higher and 25° C. or lower)/relative humidity of 40% RH or higher and 50% RH or lower.

### Laminate

According to embodiments of the present disclosure, a laminate for a chamber inner wall of a semiconductor manufacturing apparatus is provided. The laminate has a base material, an amorphous layer provided on a surface of the base material, and a crystalline layer provided on a surface of the amorphous layer. The thickness of the amorphous layer may be greater than or equal to 1 nm and less than or equal to 10 nm, the crystalline layer may be substantially composed of yttrium and fluorine, and the density of the crystalline layer can be greater than or equal to 4.7 g/cm³ and less than or equal to 5.3 g/cm³. The laminate having the above configuration can suppress the occurrence of layer irregularity or unevenness in the crystalline layer (YF₃ layer).

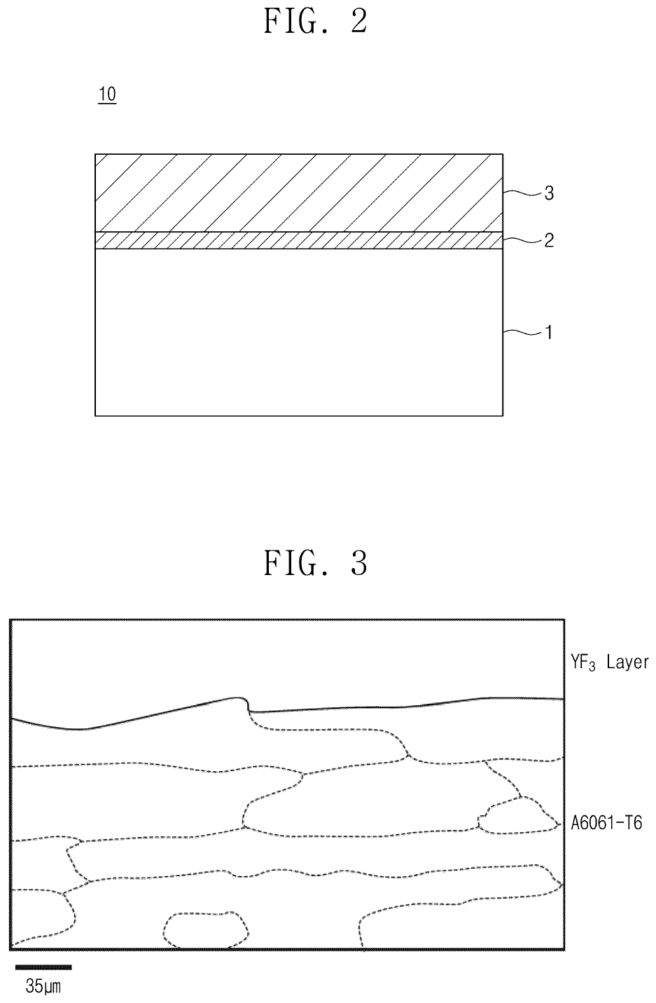

FIG. 2 is a schematic diagram of a laminate according to embodiments of the present disclosure. As shown in FIG. 2, a laminate 10 includes a base material 1, an amorphous layer 2 provided on the base material 1, and a crystalline layer 3 provided on the amorphous layer 3. The laminate 10 may be used as a chamber inner wall of a semiconductor manufacturing apparatus. The laminate 10 may be disposed such that the crystalline layer 3 is in contact with the corrosive gas. The amorphous layer 2 and the crystalline layer 3 may be provided to match the shape of the chamber inner wall, i.e., the shape of the base material 1. For example, the amorphous layer 2 and the crystalline layer 3 may be provided only on one side (one surface) of the base material 1 or on both sides (both surfaces) of the base material 1.

In the present embodiment, the laminate for a chamber inner wall of a semiconductor manufacturing apparatus according to the present disclosure is simply referred to as a “laminate”.

The mechanism of the present embodiments is described as follows.

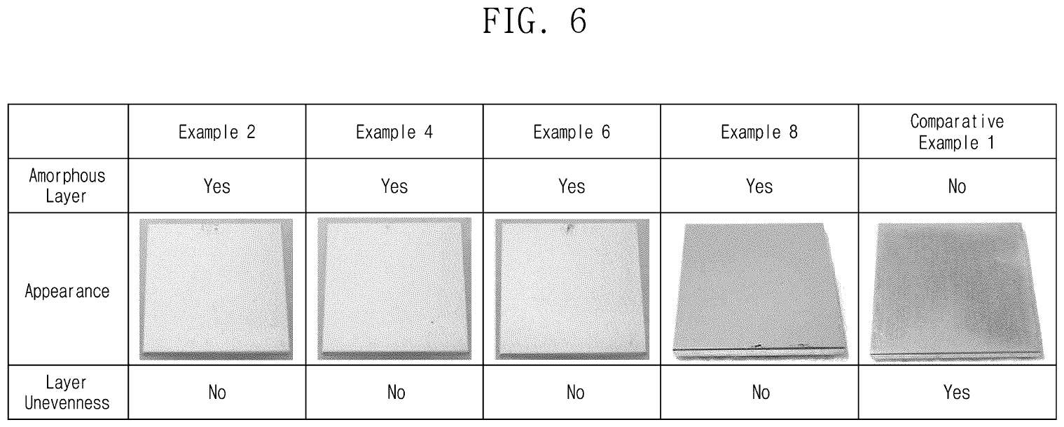

FIG. 3 is a schematic view of an SEM image of the laminate of Comparative Example 1. The Al alloy used as a base material is an aggregate of crystals having a grain size of several tens of um and has various crystal orientations. Accordingly, since the adsorption efficiency on the Al alloy surface is non-uniform, it is difficult to form a crystalline layer (YF₃ layer) having a uniform layer thickness. As shown in FIG. 6, the laminate of Comparative Example 1 did not have an amorphous layer, and layer unevenness occurred. On the other hand, in the laminate of Example 8, it was confirmed that an amorphous layer (thickness: 7 nm) was present between the base material and the crystalline layer, and the occurrence of layer unevenness was suppressed. Even when the amorphous layer in the laminate of Example 8 is a thin layer with a thickness of 7 nm, it serves as a buffer and can suppress the influence of unevenness in adsorption efficiency on the Al alloy surface, so that the occurrence of layer unevenness in the crystalline layer (YF₃ layer) can be suppressed. Since the crystalline layer in which the occurrence of layer unevenness is suppressed is smoother and has a smaller surface area, it can be less affected by plasma etching.

The foregoing mechanism is based on speculation, and whether or not it is correct does not affect the scope of the present disclosure. It is to be noted that whether or not a presumption other than those in the present specification is correct does not affect the scope of the present disclosure.

### Base Material

The laminate according to the present disclosure has a base material.

The base material of the laminate according to the present disclosure is not particularly limited. For example, the base material may include at least one of silicon, metal, and ceramic. Specific examples of the metal may be aluminum (Al), an aluminum alloy, stainless steel (SUS), titanium (Ti), or nickel (Ni). The Al alloy may be, for example, an aluminum 6000-series alloy such as A6061, A6063, or A6101. The stainless steel may be SUS304, SUS316, SUS316L, SUS420J2, or SUS630. Examples of the ceramic may be aluminum oxide (Al₂O₃), aluminum nitride (AlN), silicon carbide (SiC), or silicon nitride (Si₃N₄).

According to an embodiment, the base material may include at least one selected from the group consisting of silicon, metal, or ceramic.

According to an embodiment, the metal is at least one selected from the group consisting of Al, Al alloy, SUS, Ti, and Ni, and the ceramic may be at least one selected from the group consisting of Al₂O₃, AlN, SiC, and Si₃N₄.

The thickness of the base material may be appropriately set, and may be, for example, 1 mm or more and 10 mm or less.

### Amorphous Layer

The laminate according to the present disclosure has an amorphous layer provided on a base material, and the thickness of the amorphous layer may be greater than or equal to 1 nm and less than or equal to 10 nm.

When forming an amorphous layer with ALD, the crystalline state of the amorphous layer may be controlled by adjusting the chamber temperature.

The amorphous layer may be a single layer or a laminate of two or more layers.

It can be confirmed that the amorphous layer is amorphous by no peak being observed in X-ray diffraction. For example, in the case where the amorphous layer contains aluminum oxide or is composed of aluminum oxide, the amorphous layer does not have peaks at positions of 2θ=25.57°±1°, 35.14°±1°, and 37.76°±1° in X-ray diffraction measurement using Cu—Kα rays. In the case where the amorphous layer contains yttrium oxide or is composed of yttrium oxide, the amorphous layer does not have peaks at positions of 2θ=16.70°±1°, 20.49°±1°, 23.70°±1°, 29.13°±1°, 31.52°±1°, 33.76°±1°, 35.88°±1°, 37.89°±1°, and 39.82°±1° in X-ray diffraction measurement using Cu—Kα rays. The details of the X-ray diffraction are described in the Examples.

A material constituting the amorphous layer is not particularly limited and may be, for example, aluminum oxide (Al₂O₃) or yttrium oxide (Y₂O₃). In an embodiment, the amorphous layer comprises, and preferably consists substantially of, Al₂O₃ or Y₂O₃.

In the present specification, the fact that the amorphous layer is substantially composed of Al₂O₃ or Y₂O₃ means that the concentration of components (impurities) other than Al₂O₃ or Y₂O₃ in the amorphous layers is 5 at. % or less. The impurity may be hydrogen or carbon, derived from a source material. The concentration of impurities can be measured by X-ray photoelectron spectroscopy (XPS) and Elastic Recoil Detection Analysis (ERDA).

The thickness of the amorphous layer may be greater than or equal to 1 nm and less than or equal to 10 nm. When the thickness of the amorphous layer is less than 1 nm, a uniform crystalline layer (YF₃ layer) may not be obtained. When the thickness of the amorphous layer is more than 10 nm, the layer formation time increases and the production cost increases, which is not preferable. The thickness of the amorphous layer may be preferably 3 nm or more and 9 nm or less, and more preferably 5 nm or more and 8 nm or less. When an amorphous layer is formed by ALD, the thickness of the amorphous layer can be controlled by the ALD process conditions (e.g., the number of cycles).

The thickness of the amorphous layer can be obtained using ellipsometry, layer thickness measurement in a cross-sectional SEM image, or X-ray reflectivity measurement (XRR). In the present specification, the thickness of the amorphous layer was measured by ellipsometry.

### Crystalline Layer

The laminate according to the present disclosure has a crystalline layer provided on an amorphous layer, the crystalline layer is substantially composed of yttrium and fluorine, and the density of the crystalline layer may be 4.7 g/cm³ or more and 5.3 g/cm³ or less.

When the crystalline layer is formed by ALD, the crystalline state of the crystalline layer may be controlled by adjusting the chamber temperature.

The crystalline layer may be a single layer or a laminate of two or more layers.

It can be confirmed that the crystalline layer is crystalline by observing a peak in X-ray diffraction. According to one embodiment, the crystalline layer has peaks at least at one position of 2θ=24.03°±1°, 24.61°±1°, 25.98°±1°, 27.88°±1°, 31.00°±1°, and 36.08°±1° in X-ray diffraction measurement using Cu—Kα rays. The details of the X-ray diffraction measurements are described in the examples.

In the present specification, that the crystalline layer is substantially composed of yttrium and fluorine means that the concentration of a component (impurity) other than yttrium or fluorine is 5 at. % or less in the crystalline layer. The impurity may be hydrogen, carbon, oxygen, nitrogen, or sulfur derived from a manufacturing source material. The concentration of the impurity is the sum of the concentrations of these atoms. The concentration of carbon, oxygen, nitrogen, and sulfur can be measured by X-ray photoelectron spectroscopy (XPS), and the concentration of hydrogen can be measured by Elastic Recoil Detection Analysis (ERDA).

The density of the crystalline layer may be 4.7 g/cm³ or more and 5.3 g/cm³ or less. When the density of the crystalline layer is less than 4.7 g/cm³, the corrosion resistance is low, which is not preferable. The density of the crystalline layer is preferably high, and the upper limit thereof is 5.3 g/cm³. From the viewpoint that the effect of the present disclosure can be exerted more, the density of the crystalline layer may be preferably 5.0 g/cm³ to 5.3 g/cm³. More preferably, it may be 5.1 g/cm³ to 5.3 g/cm³. The density of the crystalline layer can be measured by X-ray reflectivity measurement (XRR).

The thickness of the crystalline layer is not particularly limited and may be, for example, 20 nm or more. The thickness of the crystalline layer may be preferably 20 nm or more and 200 nm or less, more preferably 80 nm or more and 180 nm or less, further preferably 100 nm or more and 160 nm or less, and particularly preferably 120 nm or more and 150 nm or less. When the crystalline layer is formed by ALD, the thickness of the crystalline layer can be controlled by the ALD process conditions (e.g., the number of cycles).

The thickness of the crystalline layer can be obtained using a polarization analysis method, layer thickness measurement in a cross-sectional SEM image, or X-ray reflectivity measurement (XRR). In the present specification, the thickness of the crystalline layer was measured by a polarization analysis method.

The refractive index of the crystalline layer may be, for example, 1.40 or more and 1.60 or less. Herein, the refractive index of the crystalline layer was measured by a polarization analysis method.

### Method for Producing Laminate

According to an embodiment of the present disclosure, a method for manufacturing the above-mentioned laminate is provided. The method for producing a laminate may include a step of forming a crystalline layer on the amorphous layer by atomic layer deposition (ALD). The crystalline layer forming step may include supplying a source material 1 comprising yttrium and a source material 2 comprising fluorine. The amount of the source material 1 to be supplied may be adjusted so that the number of yttrium atoms to be supplied is 1.0×10¹⁵/cm³·cycle or more.

According to an embodiment of the present disclosure, a method for manufacturing the above-mentioned laminate is provided. The method for producing a laminate may include a step of forming a crystalline layer on the amorphous layer by atomic layer deposition (ALD). The crystalline layer forming step may include supplying a source material 1 comprising yttrium and fluorine and a source material 2 comprising oxygen. The amount of the source material 1 to be supplied can be adjusted so that the number of yttrium atoms to be supplied is 1.0×10¹⁵/cm³·cycle or more.

By the above method for forming a laminate, a uniform crystalline layer (YF₃ layer) can be formed. Since the method according to the present disclosure does not require stress relaxation and adhesion improvement, occurrence of layer cracking and layer peeling of the crystalline layer (YF₃ layer) can be suppressed even on an amorphous layer having a thickness of 10 nm or less. On the other hand, according to the related art, since there is a concern that layer cracking and layer peeling of the crystalline layer may occur due to stress caused by a difference in linear expansion coefficient between the crystalline layer and the base material, an amorphous layer having a thickness of usually more than 10 nm is formed, and stress relaxation and adhesion to the crystalline layer are improved.

The method for forming a laminate according to the present disclosure may include a step of forming a crystalline layer by atomic layer deposition (ALD). The crystalline layer forming step may include supplying a source material 1 comprising yttrium and a source material 2 comprising fluorine, or supplying a source material 1 comprising yttrium and fluorine and a source material 2 comprising oxygen.

Atomic layer deposition (ALD) may be plasma ALD or thermal ALD.

The yttrium-comprising source material 1 may be tris (methylcyclopentadienyl) yttrium (Y(MeCp)₃), tris(isopropylcyclopentadienyl)yttrium (Y(i-PrCp)₃), tris (butylcyclopentadienyl) yttrium (Y(CpBu))₃), tris(ethylcyclopentadienyl) yttrium (Y(EtCp)₃), tris(N,N′-diisopropyl-2-dimethylamide-guanidinate) yttrium (Y (DPDMG)₃), Y (EtCp)₂ (iPr₂AMD), tris (N,N′-diisopropylacetamidinate) yttrium (Y (iPr₂AMD)₃), Y(iPrCp)₂ (iPr₂AMD), Y (iPrFMD)₃, tris (sec-butylcyclopentadienyl) yttrium (Y(sBuCp)₃), tris(N,N′-di-tert-butyl-formamidinate)yttrium (Y(tBu₂FMD)₃ or tris(2,2,6,6-tetramethyl-3,5-heptanedionate)yttrium (Y(thd)₃).

Source material 1 comprising yttrium and fluorine was produced using Ybeta-prime (Kamimura, S. et Al. Y₂O₃ and YF₃ thermal ALD for anti-corrosion coating, EUROCVD/Baltic ALD 2023).

The source material 2 comprising fluorine may be sulfur hexafluoride (SF₆), hydrogen fluoride pyridine (HF-pyridine), titanium tetrafluoride (TiF₄), carbon tetrafluoride (CF₄), ammonium fluorides (NH₄F), tantalum pentafluoride (TaF₅), tungsten hexafluoride (WF₆), or fluorine molecules (F₂).

The source material 2 comprising oxygen may be ozone (O₃), water (H₂O), or oxygen plasma.

Hereinafter, an example of the crystalline layer forming method will be described.

A base material having an amorphous layer on its surface is placed in a chamber of an ALD apparatus, and the temperature and pressure are adjusted as appropriate. The temperature of the chamber may be appropriately adjusted depending on the source materials to be used. The base material is heated to a desired temperature. When ALD is plasma ALD, the source material 1 comprising yttrium is Y(MeCp)₃, the source material 2 comprising fluorine is SF₆, and the temperature of the chamber may be preferably 150° C. or higher and 250° C. or lower. When ALD is thermal ALD, the source material 1 comprising yttrium and fluorine is Ybeta-prime, the source material 2 comprising oxygen is O₃, and the temperature of the chamber may be preferably higher than or equal to 300° C. and lower than or equal to 350° C. The pressure in the chamber may be, for example, 50 Pa or less.

When heating the base material, an inert gas is supplied. The inert gas may be nitrogen, argon, helium, neon, krypton, or xenon.

After adjusting the temperature and the pressure, the source material 1 is supplied. Source material 1 may be supplied in a gaseous state. The supply temperature and the supply time of the source material 1 may be appropriately set depending on the source material 1 to be used. For example, when the source material 1 is Y(MeCp)₃, the supply temperature may be about 130° C., and the supply time may be about 2 seconds. When the source material 1 is Ybeta-prime, the supply temperature may be about 120° C., and the supply time may be about 2 seconds.

The amount of the source material 1 to be supplied is adjusted so that the number of yttrium atoms to be supplied is 1.0×10¹⁵/cm³·cycle or more. When the number of yttrium to be supplied is less than 1.0×10¹⁵/cm³·cycle, the YF₃ layer may be cracked and peeled. The upper limit of the number of yttrium atoms to be supplied is not particularly limited, and may be preferably 1.0×10¹⁶/cm³·cycle or less, and more preferably 5.5×10¹⁵/cm³·cycle or less from the viewpoint of price.

The number of atoms to be supplied is calculated as the number of atoms by the following formula:

Number of atoms supplied [number/cm³·cycle)]=Amount of source material supplied [g/cycle]÷source material mass [g/mol]×6.02×10²³ [number/mol]÷chamber volume [cm³].

After the supply of the source material 1, the source material 1 is purged while flowing an inert gas. The purge time may be set arbitrarily.

After purging, source material 2 is supplied. The source material 2 may be supplied in a gaseous state. The supply temperature and the supply time of the source material 2 can be appropriately set depending on the kind of the source material to be used. For example, when the source material 2 is SF₆ or O₃, the supply temperature may be room temperature (e.g., 23° C.±2° C.), and the supply time may be about 9 seconds. When the source material 2 is HF-pyridine, the supply temperature may be about 50° C., and the supply time may be about 1 second.

After the supply of the source material 2, the source material 2 is purged while flowing an inert gas. The purge time can be set arbitrarily.

The supply and the purge of the source material 1 and the supply and the pudge of the source material 2 are referred to as one cycle. The number of cycles can be appropriately set so that the crystalline layer has a desired thickness.

In the above-described method, the crystalline layer is formed.

In one embodiment, the method for forming a laminate according to the present disclosure may include a step of forming an amorphous layer on the surface of the base material by atomic layer deposition (ALD) before the crystalline layer forming step. At this time, the amorphous layer and the crystalline layer may be formed in the same chamber.

Hereinafter, the crystalline layer forming step in the case where the amorphous layer comprises Al₂O₃ will be described.

In the amorphous layer forming step, as in the crystalline layer forming step described above, the supply and the purge of the source material 1 and the supply and the purge of the source material 2 are referred to as one cycle. The number of cycles can be appropriately set so that the amorphous layer has a desired thickness. Hereinafter, in the amorphous layer forming step, the source material 1 is referred to as the source material ‘a’, and the source material 2 is referred to as the source material ‘b’.

The base material is placed in the chamber of the ALD apparatus, and the temperature and pressure are adjusted as appropriate. The chamber temperature and the pressure in the chamber may be set to be the same as the chamber temperature and pressure in the chamber described in the crystalline layer formation process.

An inert gas is supplied when heating the base material. The inert gas may be nitrogen, argon, helium, neon, krypton, or xenon.

After adjusting the temperature and the pressure, the source material ‘a’ is supplied. The source material ‘a’ may be supplied in a gaseous state. The source material ‘a’ of the crystalline layer forming step may be trimethylaluminum (TMA), triethylaluminum (TEA), or trichloroaluminum.

The supply temperature and supply time of the source material ‘a’ can be appropriately set depending on the kind of the source material ‘a’ to be used. For example, when the source material ‘a’ is TMA, the supply temperature may be room temperature (e.g., 23° C.±2° C.), and the supply time may be about 0.15 seconds.

After the supply of the source material ‘a’, the source material ‘a’ may be purged while flowing an inert gas. The purge time can be set arbitrarily.

After purging, the source material ‘b’ is supplied. The source material ‘b’ may be supplied in a gaseous state. The source material ‘b’ of the crystalline layer forming step may be oxygen, ozone, water, or oxygen plasma.

The supply temperature and the supply time of the source material ‘b’ can be appropriately set depending on the kind of the source material ‘b’ to be used. For example, when the source material ‘b’ is O₂, the supply temperature may be room temperature (e.g., 23° C.±2° C.), and the supply time may be about 3 seconds.

After the supply of the source material ‘b’, the source material ‘b’ is purged while flowing an inert gas. The purge time can be set arbitrarily.

In the above-described method, an amorphous layer is be formed.

### Semiconductor Manufacturing Apparatus

One embodiment of the present disclosure is a semiconductor manufacturing apparatus having the above-described laminate provided in a chamber inner wall.

The laminate according to the present disclosure has a crystalline layer (YF₃ layer) on the surface thereof. Since the YF₃ layer is formed uniformly and layer cracking and layer peeling is suppressed, it can be used as a chamber inner wall of a semiconductor manufacturing apparatus. The semiconductor manufacturing apparatus is not particularly limited and may be a conventionally and widely known apparatus.

Although the embodiments of the present disclosure have been described in detail, it should be apparent that the embodiments are illustrative and not restrictive, and the scope of the present disclosure should be construed by the claims.

### EMBODIMENTS

The present disclosure will be described in more detail with reference to the following Examples and Comparative Examples, but the technical scope of the present disclosure is not limited to the following Examples.

### Example 1

A base material (silicon base material, A/R 10, thickness 2 mm) was placed in a chamber of an ALD apparatus, and the chamber was evacuated to 50 Pa or less. The base material was heated to 250° C. for 10 minutes. Heating was performed while flowing nitrogen gas, which is an inert gas.

Next, an amorphous layer was formed on the base material, and then a crystalline layer was formed on the amorphous layer. The amorphous layer and the crystalline layer were formed in the same chamber (chamber temperature: 250° C.).

An amorphous layer (Al₂O₃ layer) was formed by a plasma enhanced ALD (PEALD) method using trimethylaluminum (TMA) as a source material ‘a’ and O₂ as a source material ‘b’. The supply temperature of the source material ‘a’ and the source material ‘b’ was 23° C.±2° C. The feeding time of the source material ‘a’ was 0.15 seconds, the feeding time of the starting material ‘b’ was 3 seconds, and an arbitrary purge time was provided between each feeding. The above process is defined as one cycle. 60 cycles were repeated to form an Al₂O₃ layer having a layer thickness of 7 nm. During the supply of the source material ‘b’, discharge was performed at RF 100 W using a CCP type electrode. The amount of the source material ‘a’ supplied was adjusted so that the number of Al atoms supplied was 1.0×10¹⁵/cm³·cycle, and the amount of the starting material ‘b’ supplied was adjusted so that a number of O atoms supplied was 1.5×10¹⁵/cm³·cycle.

A crystalline layer YF₃ layer was formed by a PEALD method using tris (methylcyclopentadienyl) yttrium (Y(MeCp)₃) as a source material 1 and SF₆ as a source material 2. The supply temperature of the source material 1 was 130° C., and the supply temperature of the source material 2 was 23° C.±2° C. The feeding time of the source material 1 was 2 seconds, the feeding time of the source material 2 was 9 seconds, and an arbitrary purge time was provided between each feeding. The above process is defined as one cycle. 3000 cycles were repeated to form a YF₃ layer having a layer thickness of 128 nm. During the feeding of the source material 2, discharge was performed at RF 100 W using a CCP type electrode. The amount of the source material 1 supplied was adjusted so that the number of Y atoms supplied was 1.5×10¹⁵/cm³·cycle, and the amount of the source material 2 supplied was adjusted so as to adjust the number of F atoms supplied to 3.0×10¹⁵/cm³·cycles

After the formation of the crystalline layer, the chamber was vented, and the laminate was taken out.

The number of atoms supplied was calculated by the following formula:

Feed number of atoms [number/cm³·cycle]=Feed amount of source material [g/cycle]÷source material mass [g/mol]×6.02×10²³ [number/mol]÷chamber volume [cm³].

### Example 2

A laminate was produced in the same manner as in Example 1 except that an aluminum alloy (A6061) base material (A/R 10, thickness 2 mm) was used as the base material instead of the silicon base material.

### Example 3

A laminate was produced in the same manner as in Example 1 except that the heating temperature and the chamber temperature for the base material were changed from 250° C. to 200° C., and the thickness of the crystalline layer was changed from 128 nm to 134 nm.

### Example 4

A laminate was produced in the same manner as in Example 2 except that the heating temperature and the chamber temperature for the base material were changed from 250° C. to 200° C., and the thickness of the crystalline layer was changed from 128 nm to 134 nm.

### Example 5

A laminate was produced in the same manner as in Example 1 except that the heating temperature and the chamber temperature for the base material were changed from 250° C. to 150° C., and the thickness of the crystalline layer was changed from 128 nm to 145 nm.

### Example 6

A laminate was produced in the same manner as in Example 2 except that the heating temperature and the chamber temperature for the base material were changed from 250° C. to 150° C., and the thickness of the crystalline layer was changed from 128 nm to 145 nm.

### Example 7

A base material (silicon base material, A/R 10, thickness 2 mm) was placed in a chamber of an ALD apparatus, and the chamber was evacuated to 50 Pa or less. The base material was heated to 350° C. for 10 minutes. Heating was performed while flowing nitrogen gas, which is an inert gas.

Next, an amorphous layer was formed on the base material, and then a crystalline layer was formed on this amorphous layer. The amorphous and crystalline layers were deposited in the same chamber (chamber temperature: 350° C.).

An amorphous layer (Al₂O₃ layer) was formed by a thermal ALD method using TMA as a source material ‘a’ and H₂O as a source material ‘b’. The supply temperature of the source materials ‘a’ and ‘b’ was 23° C.±2° C. The feeding time of the source material ‘a’ was 0.15 seconds, the feeding time of the source material ‘b’ was 0.15 seconds, and an arbitrary purge time was provided between each feeding. The above process is defined as one cycle. After 75 cycles, an Al₂O₃ layer having a thickness of 7 nm was formed. The amount of the source material ‘a’ supplied was adjusted so that the number of Al atoms supplied was 1.0×10¹⁵/cm³·cycle, and the amount of the starting material ‘b’ supplied was adjusted so that a number of O atoms supplied was 1.5×10¹⁵/cm³·cycle.

As source material 1, Ybeta-prime (Kamimura, S. et Al. Y₂O₃ and YF₃ thermal ALD for anti-corrosion coating, EUROCVD/Baltic ALD 2023) was used, and using O₃ as source material 2 and using a thermal ALD method, a crystalline layer (YF₃ layer) was formed. The supply temperature of the source material 1 was 120° C., and the supply temperature of the source material 2 was 23° C.±2° C. The feeding time of source material 1 was 2 seconds, the feeding time of source material 2 was 5 seconds, and an arbitrary purge time was provided between each feeding. The above process is defined as one cycle. 1700 cycles were repeated to form a YF₃ layer having a thickness of 127 nm. The amount of the source material 1 supplied was adjusted so that the number of Y atoms supplied was 5.5×10¹⁵/cm³·cycle, and the amount of the source material 2 supplied was adjusted so as to adjust the number of O atoms supplied to 1.7×10¹⁶/cm³·cycle.

After the formation of the crystalline layer, the chamber was vented, and the laminate was taken out.

### Example 8

A laminate was produced in the same manner as in Example 7 except that an aluminum alloy (A6061) base material (A/R 10, thickness 2 mm) was used as the base material in place of the silicon base material.

### Example 9

A laminate was produced in the same manner as in Example 7 except that the thickness of the crystalline layer was changed from 127 nm to 21 nm and the number of cycles in the formation of the crystalline layer was changed from 1700 cycles to 300 cycles.

### Comparative Example 1

A base material (aluminum alloy (A6061) base material (A/R 10, thickness 2 mm)) was placed in a chamber of an ALD apparatus, and the chamber was evacuated to 50 Pa or less. The base material was heated to 350° C. for 10 minutes. Heating was performed while flowing nitrogen gas, which is an inert gas.

Next, a crystalline layer was formed on the base material (chamber temperature: 350° C.).

A crystalline layer (YF₃ layer) was formed by a thermal ALD method using Ybeta-prime as the source material 1 and O₃ as the source material 2 of the second gas. The supply temperature of the source material 1 was 120° C., and the supply temperature of the source material 2 was 23° C.±2° C. The feeding time of source material 1 was 2 seconds, the feeding time of source material 2 was 5 seconds, and an arbitrary purge time was provided between each feeding. The above process is defined as one cycle. After 3000 cycles, a YF₃ layer having a thickness of 117 nm was formed. The amount of the source material 1 supplied was adjusted so that the number of Y atoms supplied was 5.5×10¹⁵/cm³·cycle, and the amount of the source material 2 supplied was adjusted so as to adjust the number of O atoms supplied to 1.7×10¹⁶/cm³·cycle.

After the formation of the crystalline layer, the chamber was vented, and the laminate was taken out.

### Comparative Example 2

A base material (silicon base material, A/R 10, thickness 2 mm) was placed in a chamber of an ALD apparatus, and the chamber was evacuated to 50 Pa or less. The base material was heated to 250° C. for 10 minutes. Heating was performed while flowing nitrogen gas, which is an inert gas.

Then, an amorphous layer was formed on the base material (chamber temperature: 250° C.).

An amorphous layer (YF₃ layer) was formed by a thermal ALD method using Ybeta-prime as a source material ‘a’ and O₃ as a source material ‘b’. The supply temperature of the source material ‘a’ was 120° C., and the supply temperature of the source material ‘b’ was 23° C.±2° C. The feeding time of the source material ‘a’ was 2 seconds, the feeding time of the source material ‘b’ was 5 seconds, and an arbitrary purge time was provided between each feeding. The above process is defined as one cycle. 2200 cycles were repeated to form a YF₃ layer having a thickness of 17 nm. The amount of the source material ‘a’ supplied was adjusted so that the number of Y atoms supplied was 5.5×10¹⁵/cm³·cycle, and the amount of the source material ‘b’ supplied was adjusted so as to adjust the number of O atoms supplied to 1.7×10¹⁶/cm³·cycle.

After the formation of the amorphous layer, the chamber was vented, and the laminate was taken out.

### Comparative Example 3

A base material (silicon base material, A/R 10, thickness 2 mm) was placed in a chamber of an ALD apparatus, and the chamber was evacuated to 50 Pa or less. The base material was heated to 300° C. for 10 minutes. Heating was performed while flowing nitrogen gas, which is an inert gas.

Next, a crystalline layer was formed on the base material (chamber temperature: 300° C.).

A crystalline layer (YF₃ layer) was formed by a thermal ALD method using tris (isopropylcyclopentadienyl) yttrium (Y (i-PrCp)₃) as a source material 1 and hydrogen fluoride pyridine (HF-Pyridine) as a source material 2. The supply temperature of the source material 1 was 160° C., and the supply temperature of the source material 2 was 50° C. The feeding time of the source material 1 was 30 seconds, the feeding time of the source material 2 was 1 second, and an arbitrary purge time was provided between each feeding. The above process is defined as one cycle. After repeating 1300 cycles, a YF₃ layer having a thickness of 79 nm was formed. The amount of the source material 1 supplied was adjusted so that the number of Y atoms supplied was 2.6×10¹⁴/cm³ cycles, and the amount of the source material 2 supplied was adjusted so as to adjust the number of F atoms supplied to 7.8×10¹⁴/cm³ cycles.

After the formation of the crystalline layer, the chamber was vented and the laminate was taken out.

### Comparative Example 4

A base material (silicon base material, thickness 2 mm) was placed in a chamber of an ALD apparatus, and the chamber was evacuated to 50 Pa or less. The base material was heated to 200° C. for 10 minutes. Heating was performed while flowing nitrogen gas, which is an inert gas.

Next, an amorphous layer was formed on the base material (chamber temperature: 200° C.).

An amorphous layer (Al₂O₃ layer) was formed by a thermal ALD method using TMA as a source material ‘a’ and H₂O as a source material ‘b’. The supply temperature of the source material ‘a’ and the source material ‘b’ was 23° C.±2° C. The feeding time of the source material ‘a’ was 0.15 seconds, the feeding time of the source material ‘b’ was 0.15 seconds, and an arbitrary purge time was provided between each feeding. The above process is defined as one cycle. After 1000 cycles, an Al₂O₃ layer having a thickness of 111 nm was formed. The amount of the source material ‘a’ supplied was adjusted so that the number of Al atoms was 9.2×10¹⁵/cm³·cycle, and the supply amount of the source material ‘b’ was adjusted so that a supply number of O atoms was 1.4×10¹⁶/cm³·cycle.

After the formation of the amorphous layer, the chamber was vented, and the laminate was taken out.

The production conditions of the crystalline layers of the laminates of Examples 1 to 9 and Comparative Examples 1 and 3 are summarized in Table 1. The production conditions of the amorphous layers of the laminates of Examples 1 to 9 and Comparative Examples 2 and 4 are summarized in Table 2.

TABLE 1

| | Source material 1 | | Source material 2 | | | |
|---|---|---|---|---|---|---|
| | | Number of atoms | | Number of atoms | | Chamber |
| | Source | supplied | Source | supplied | | temperature |
| | material | (/cm³ cycles) | material | (/cm³ cycles) | Method | (° C.) |
| Examples 1 | Y(MeCp)₃ | 1.5 × 10¹⁵ | SF₆ | 3.0 × 10¹⁵ | PEALD | 250 |
| | | (yttrium) | | (fluorine) | | |
| Examples 2 | Y(MeCp)₃ | 1.5 × 10¹⁵ | SF₆ | 3.0 × 10¹⁵ | PEALD | 250 |
| | | (yttrium) | | (fluorine) | | |
| Examples 3 | Y(MeCp)₃ | 1.5 × 10¹⁵ | SF₆ | 3.0 × 10¹⁵ | PEALD | 200 |
| | | (yttrium) | | (fluorine) | | |
| Examples 4 | Y(MeCp)₃ | 1.5 × 10¹⁵ | SF₆ | 3.0 × 10¹⁵ | PEALD | 200 |
| | | (yttrium) | | (fluorine) | | |
| Examples 5 | Y(MeCp)₃ | 1.5 × 10¹⁵ | SF₆ | 3.0 × 10¹⁵ | PEALD | 150 |
| | | (yttrium) | | (fluorine) | | |
| Examples 6 | Y(MeCp)₃ | 1.5 × 10¹⁵ | SF₆ | 3.0 × 10¹⁵ | PEALD | 150 |
| | | (yttrium) | | (fluorine) | | |
| Examples 7 | Ybeta- | 5.5 × 10¹⁵ | Ozone | 1.7 × 10¹⁶ | Thermal | 350 |
| | prime | (yttrium) | | (oxygen) | ALD | |
| Examples 8 | Ybeta- | 5.5 × 10¹⁵ | Ozone | 1.7 × 10¹⁶ | Thermal | 350 |
| | prime | (yttrium) | | (oxygen) | ALD | |
| Examples 9 | Ybeta- | 5.5 × 10¹⁵ | Ozone | 1.7 × 10¹⁶ | Thermal | 350 |
| | prime | (yttrium) | | (oxygen) | ALD | |
| Comparative | Ybeta- | 5.5 × 10¹⁵ | Ozone | 1.7 × 10¹⁶ | Thermal | 350 |
| Example 1 | prime | (yttrium) | | (oxygen) | ALD | |
| Comparative | Y(i-PrCp)₃ | 2.6 × 10¹⁴ | HF- | 7.8 × 10¹⁴ | Thermal | 300 |
| Example 3 | | (yttrium) | Pyridine | (fluorine) | ALD | |

TABLE 2

| | Source material ‘a’ | | Source material ‘b’ | | | |
|---|---|---|---|---|---|---|
| | | Number of | | Number of | | |
| | | atoms | | atoms | | Chamber |
| | source | supplied | source | supplied | | temperature |
| | material | (/cm³ cycles) | material | (/cm³ cycles) | Method | (° C.) |
| Examples 1 | TMA | 1.0 × 10¹⁵ | O₂ | 1.5 × 10¹⁵ | PEALD | 250 |
| | | (Al) | | (oxygen) | | |
| Examples 2 | TMA | 1.0 × 10¹⁵ | O₂ | 1.5 × 10¹⁵ | PEALD | 250 |
| | | (Al) | | (oxygen) | | |
| Examples 3 | TMA | 1.0 × 10¹⁵ | O₂ | 1.5 × 10¹⁵ | PEALD | 250 |
| | | (Al) | | (oxygen) | | |
| Examples 4 | TMA | 1.0 × 10¹⁵ | O₂ | 1.5 × 10¹⁵ | PEALD | 250 |
| | | (Al) | | (oxygen) | | |
| Examples 5 | TMA | 1.0 × 10¹⁵ | O₂ | 1.5 × 10¹⁵ | PEALD | 250 |
| | | (Al) | | (oxygen) | | |
| Examples 6 | TMA | 1.0 × 10¹⁵ | O₂ | 1.5 × 10¹⁵ | PEALD | 250 |
| | | (Al) | | (oxygen) | | |
| Examples 7 | TMA | 1.0 × 10¹⁵ | H₂O | 1.5 × 10¹⁵ | Thermal | 350 |
| | | (Al) | | (oxygen) | ALD | |
| Examples 8 | TMA | 1.0 × 10¹⁵ | H₂O | 1.5 × 10¹⁵ | Thermal | 350 |
| | | (Al) | | (oxygen) | ALD | |
| Examples 9 | TMA | 1.0 × 10¹⁵ | H₂O | 1.5 × 10¹⁵ | Thermal | 350 |
| | | (Al) | | (oxygen) | ALD | |
| Comparative | Ybeta- | 5.5 × 10¹⁵ | Ozone | 1.7 × 10¹⁶ | Thermal | 250 |
| Example 2 | prime | (yttrium) | | (oxygen) | ALD | |
| Comparative | TMA | 9.2 × 10¹⁵ | H₂O | 1.4 × 10¹⁶ | Thermal | 200 |
| Example 4 | | (Al) | | (oxygen) | ALD | |

### Evaluation

The laminate produced above is evaluated as follows.

### Layer Thickness and Refractive Index Measurement

The layer thicknesses and refractive indices of the laminates of Examples 1 to 9 and Comparative Examples 1 to 4 were measured by a polarization analysis method. The results are shown in Table 3.

### Layer Density Measurement

The layer density of the crystalline layers of the laminates of Examples 1 to 9 and Comparative Examples 1 and 3 and the layer density of the amorphous layer of the laminate of Comparative Examples 2 and 4 were measured by an X-ray reflectivity measurement (XRR) using a fully automatic sample horizontal multipurpose X-ray diffractometer (product name: Smart-Lab, manufactured by Rigaku Corporation). The results are shown in Table 3.

### Evaluation of Crystallinity

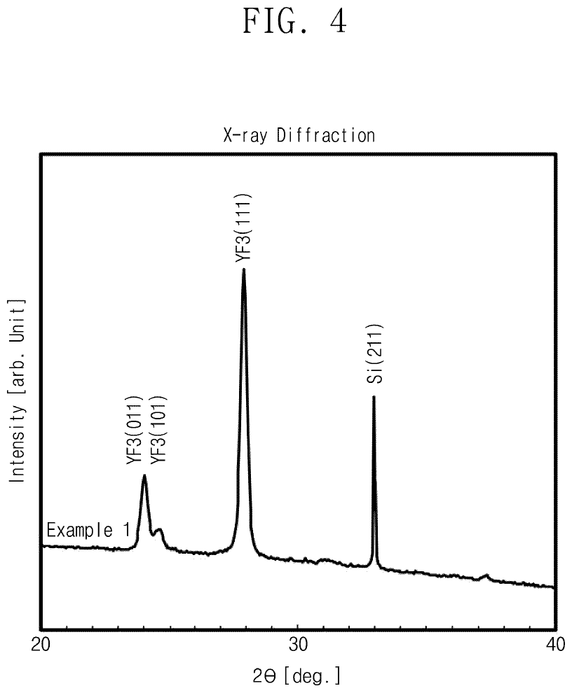

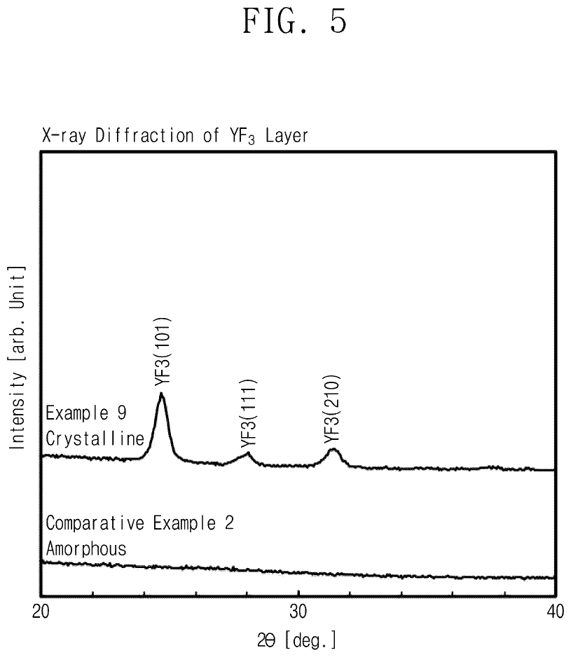

The crystallinity of the laminates of Examples 1 to 9 and Comparative Examples 1 to 4 was evaluated by X-ray diffraction measurement (XRD). A fully automatic sample horizontal multipurpose X-ray diffractometer (product name: Smart-Lab, manufactured by Rigaku Corporation) was used for the X-ray diffraction measurement. The target of the X-ray tube was Cu, and the measurement was performed at intervals of 0.05° from 2θ=3° to 80°. Results are shown in Table 3, FIG. 4, and FIG. 5.

As shown in Table 3, the crystalline layer and the amorphous layer in the laminates of Examples 1 to 9 appear to be crystalline and amorphous, respectively. The crystalline layer in the laminates of Comparative Examples 1 and 3 appears to be crystalline, and the amorphous layer in the laminates of Comparative Examples 2 and 4 appears to be amorphous.

FIG. 4 is a measurement result of the laminate of Example 1. As shown in FIG. 4, the XRD peaks in the laminate of Example 1 are only YF3 and Si, so that the crystalline layer (YF₃ layer) appears to be crystalline.

FIG. 5 shows the measurement results of the crystalline layer (YF₃ layer) of the laminate of Example 9 and the amorphous layer (YF₃ layer) of the laminate of Comparative Example 2. As shown in FIG. 5, the crystalline layer (YF₃ layer) of the laminate of Example 9 appears to be crystalline, and the amorphous layer (YF₃ layer) of the laminate of Comparative Example 2 appears to be amorphous.

### Evaluation of Layer Unevenness

Visual sensory evaluation was performed on the laminates of Examples 2, 4, 6, 8, and Comparative Example 1. The results are shown in Table 3 and FIG. 6.

As shown in Table 3 and FIG. 6, since the laminates of Examples 2, 4, 6, and 8 had an amorphous layer and thus the influence of the base material could be suppressed, a crystalline layer of YF₃ having a more uniform layer could be formed. Accordingly, since the crystalline layer of YF₃ is smooth and has a small surface area, there is an advantage that it can be less affected by plasma etching.

### Evaluation of Layer Peeling and Layer Cracking

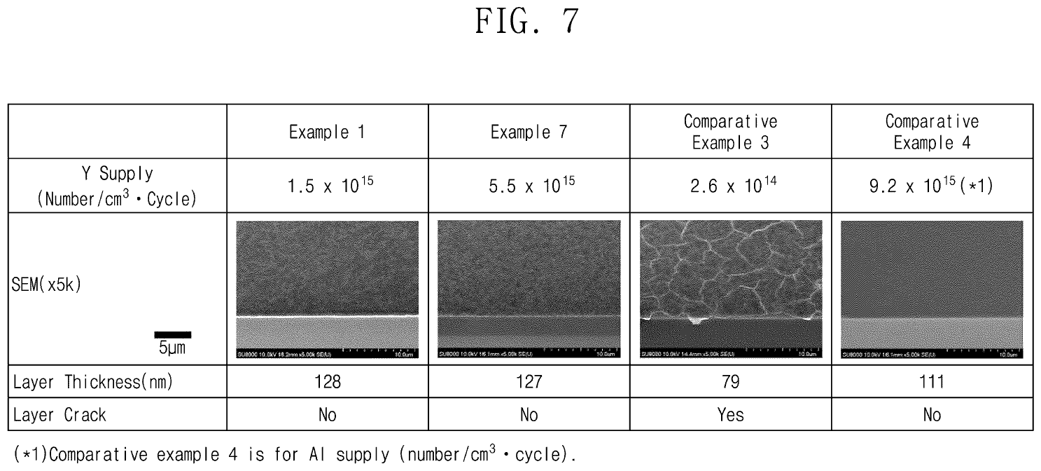

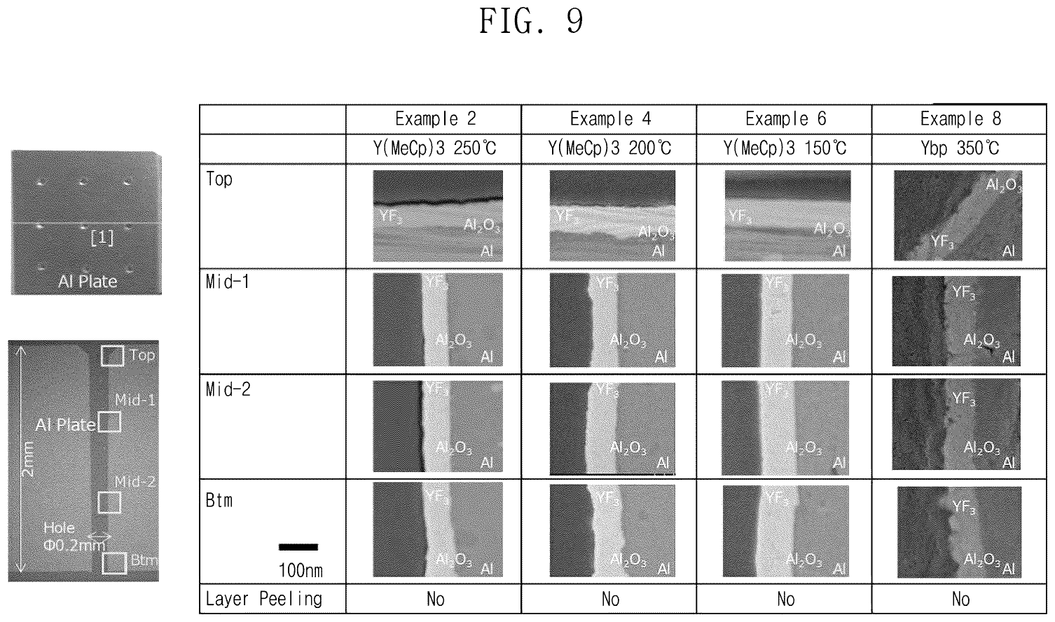

A scanning electron microscope (SEM) image (5000×, 10000×, or 200000×) of a cross section of each of the laminates of Examples 1 to 9 and Comparative Examples 1 to 4 was taken. The presence or absence of layer peeling was determined by the presence or absence of a gap at the interface between the base material and the layer in the SEM image. The results are shown in Table 3 and FIGS. 7, 8 and 9. As shown in FIG. 9, the laminate was cut along line [1], and a cross-sectional SEM was taken.

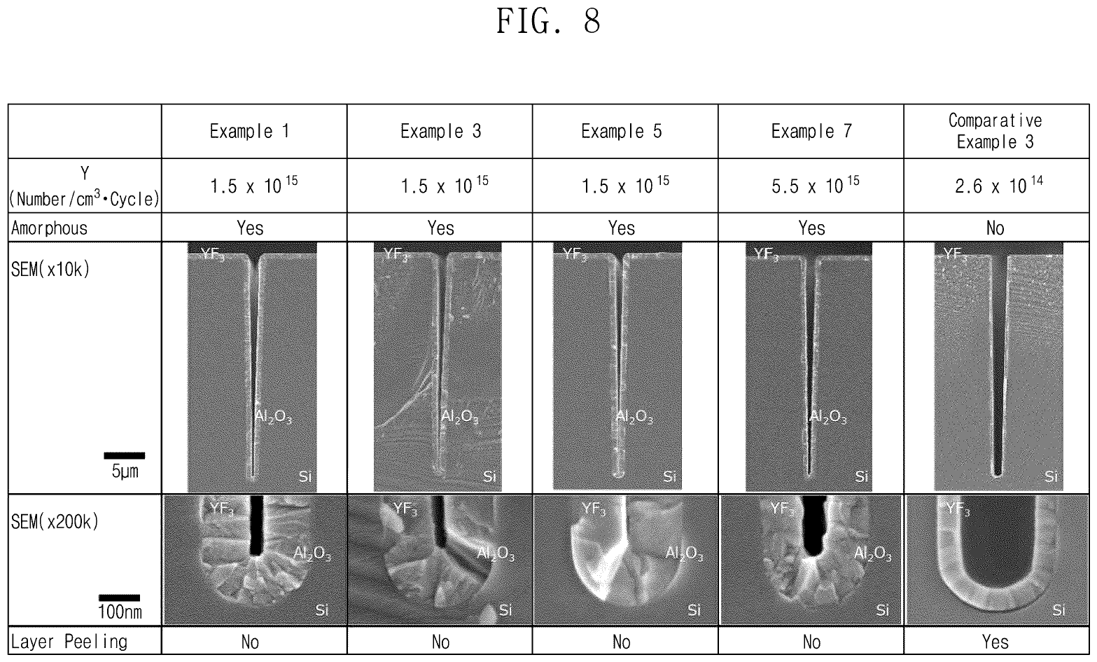

As shown in Table 3, FIG. 7, FIG. 8, and FIG. 9, the laminates of Examples 1 to 9 and Comparative Examples 1, 2 and 4 were formed by setting the number of yttrium atoms supplied to 1.0×10¹⁵/cm³·cycle or more, and layer peeling and layer cracking did not occur. On the other hand, since the laminate of Comparative Example 3 was formed under the condition that the number of yttrium atoms supplied was not sufficient due to the number of yttrium atoms supplied being 2.6×10¹⁴/cm³·cycle, layer peeling occurred.

### Measurement of Impurity Concentration

The concentrations of carbon, oxygen, nitrogen, and sulfur among impurities in the crystalline layer (YF₃ layer) of the laminates of Examples 1, 5, 7, and 9 and Comparative Example 2 and the amorphous layer (YF₃ layer) of the laminate of Comparative Example 3 were measured by X-ray photoelectron spectroscopy (XPS), and the concentration of hydrogen was measured by elastic recoil detection analysis (ERDA). The results are shown in Table 3. The results in Table 3 are the sum of the concentrations of the respective impurities.

As shown in Table 3, the impurity concentration in the YF₃ layer which is a crystalline layer is lower than that in the YF₃ which is an amorphous layer.

### Al₂O₃ normalized Etching Depth

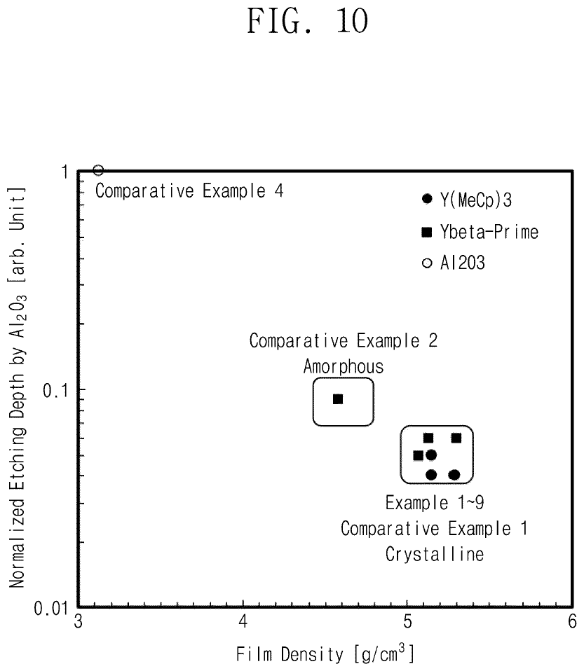

The laminates of Examples 1 to 9 and Comparative Examples 1 to 4 were etched using an ICP etching apparatus. The RF power was ICP 1500 W, the Bias was 30 W, the CF gas supply was 4120 sccm, the O₂ gas supply was 30 sccm, the pressure was 1 Pa, and the etching time was 5 hours. The etch depth was measured using polarimetry and cross-sectional SEM, and the etch depth was normalized and compared based on the Al₂O₃ layer. The results are shown in Table 3 and FIG. 10.

As shown in Table 3 and FIG. 10, the crystalline layer (YF₃ layer) of the laminates of Examples 1 to 9 and Comparative Example 1 appear to have high corrosion resistance. On the other hand, the amorphous layers (YF₃ layer and Al₂O₃ layer) of the laminates of Comparative Examples 2 and 4 appear to have low corrosion resistance. The crystalline layer (YF₃ layer) of Comparative Example 3 was delaminated and appeared to have low corrosion resistance.

TABLE 3

| | | Amorphous layer | | | Crystalline layer | | | |
|---|---|---|---|---|---|---|---|---|
| | Base | Type | Layer | | Type | Layer | | layer |
| | material | of | thickness | Crystalline | of | thickness | Refractive | density |
| | Material | layer | (nm) | state | layer | (nm) | index | (g/cm²) |
| Examples 1 | Si | Al₂O₃ | 7 | Amorphous | YF₃ | 128 | 1.55 | 5.2 |
| Examples 2 | A6061 | Al₂O₃ | 7 | Amorphous | YF₃ | 128 | 1.55 | 5.2 |
| Examples 3 | Si | Al₂O₃ | 7 | Amorphous | YF₃ | 134 | 1.55 | 5.3 |
| Examples 4 | A6061 | Al₂O₃ | 7 | Amorphous | YF₃ | 134 | 1.55 | 5.3 |
| Examples 5 | Si | Al₂O₃ | 7 | Amorphous | YF₃ | 145 | 1.56 | 5.2 |
| Examples 6 | A6061 | Al₂O₃ | 7 | Amorphous | YF₃ | 145 | 1.56 | 5.2 |
| Examples 7 | Si | Al₂O₃ | 7 | Amorphous | YF₃ | 127 | 1.55 | 5.3 |
| Examples 8 | A6061 | Al₂O₃ | 7 | Amorphous | YF₃ | 127 | 1.55 | 5.3 |
| Examples 9 | Si | Al₂O₃ | | Amorphous | YF₃ | 21 | 1.42 | 5.1 |
| Comparative | A6061 | — | — | — | YF₃ | 117 | 1.55 | 5.3 |
| Example 1 | | | | | | | | |
| Comparative | Si | YF₃ | 17 | Amorphous | — | — | — | — |
| Example 2 | | | | | | | | |
| Comparative | Si | — | — | — | YF₃ | 79 | 1.51 | 5.3 |
| Example 3 | | | | | | | | |
| Comparative | Si | Al₂O₃ | 111 | Amorphous | — | — | — | — |
| Example 4 | | | | | | | | |

| | | Evaluation | | | |
|---|---|---|---|---|---|
| | | | | | Al₂O₃ |
| | Crystalline layer | | | Impurity | normalized |
| | Crystalline | | peeling | Concentration | Etching Depth |
| | state | unevenness | cracking | (at. %) | ( [symbol] rb. unit) |
| Examples 1 | Crystalline | — | No | <3.9 | 0.04 |
| Examples 2 | Crystalline | No | No | — | 0.04 |
| Examples 3 | Crystalline | — | No | — | 0.04 |
| Examples 4 | Crystalline | No | No | — | 0.04 |
| Examples S | Crystalline | — | No | <4.1 | 0.05 |
| Examples 6 | Crystalline | No | No | — | 0.05 |
| Examples 7 | Crystalline | — | No | <3.6 | 0.06 |
| Examples 8 | Crystalline | No | No | — | 0.06 |
| Examples 9 | Crystalline | — | No | <4.3 | 0.05 |
| Comparative | Crystalline | Yes | No | — | 0.06 |
| Example 1 | | | | | |
| Comparative | — | — | No | <6.2 | 0.09 |
| Example 2 | | | | | |
| Comparative | Crystalline | — | Yes | <3.4 | 0.10 |
| Example 3 | | | | | |
| Comparative | — | — | No | — | 1.00 |
| Example 4 | | | | | |

[symbol]

indicates data missing or illegible when filed

The amorphous layer of the comparative example 2: refractory index 1.38, layer density 4.6 g/cm³

The amorphous layer of the comparative example 4: layer density 3.1 g/cm³

According to the present disclosure, a YF₃ layer without unevenness or irregularity may be formed on an inner wall of a chamber of a semiconductor manufacturing apparatus.

While embodiments are described above, a person skilled in the art may understand that many modifications and variations are made without departing from the spirit and scope of the disclosure defined in the following claims. Accordingly, the example embodiments of the disclosure should be considered in all respects as illustrative and not restrictive, with the spirit and scope of the disclosure being indicated by the appended claims.

What is claimed is:

1. A laminate for a chamber inner wall of a semiconductor manufacturing apparatus, comprising:
a base material;
an amorphous layer on the base material; and
a crystalline layer on the amorphous layer,
wherein the amorphous layer has a thickness of 1 nm or more and 10 nm or less, and
wherein the crystalline layer comprises yttrium and fluorine, and
wherein the crystalline layer has a density of 4.7 g/cm³ or more and 5.3 g/cm³ or less.

2. The laminate of claim 1, wherein the crystalline layer has at least one peak among 2θ=24.03°±1°, 24.61°±1°, 25.98°±1°, 27.88°±1°, 31.00°±1°, and 36.08°±1° positions in X-ray diffraction measurement using Cu—Kα rays.

3. The laminate of claim 1, wherein the amorphous layer comprises aluminum oxide or yttrium oxide.

4. The laminate of claim 1, wherein the base material comprises at least one of silicon, metal, and ceramic.

5. The laminate of claim 4, wherein the metal is at least one of an aluminum alloy, stainless steel (SUS), titanium, and nickel, and
the ceramic is at least one of aluminum oxide, aluminum nitride, silicon carbide, and silicon nitride.

6. The laminate of claim 1, wherein the base material has a thickness of 1 mm or more and 10 mm or less.

7. The laminate of claim 1, wherein a concentration of a component other than Al₂O₃ or Y₂O₃ in the amorphous layer is 5 at. % or less.

8. The laminate of claim 1, wherein a concentration of a component other than yttrium and fluorine in the crystalline layer is 5 at. % or less.

9. The laminate of claim 1, wherein the crystalline layer has a thickness of 20 nm or more and 200 nm or less.

10. The laminate of claim 1, wherein the refractive index of the crystalline layer is 1.40 or more and 1.60 or less.

11. A laminate for a chamber inner wall of a semiconductor manufacturing apparatus, comprising:
a base material;
an amorphous layer on the base material; and
a crystalline layer on the amorphous layer,
wherein the amorphous layer has a thickness of 1 nm or more and 10 nm or less,
wherein the crystalline layer is a YF₃ layer, and
wherein a concentration of a component other than yttrium and fluorine in the crystalline layer is 5 at. % or less.

12. The laminate of claim 11, wherein the crystalline layer has at least one peak among 2θ=24.03°±1°, 24.61°±1°, 25.98°±1°, 27.88°±1°, 31.00°±1°, and 36.08°±1° positions in X-ray diffraction measurement using Cu—Kα rays.

13. The laminate of claim 11, wherein the amorphous layer comprises aluminum oxide or yttrium oxide.

14. The laminate of claim 11, wherein the base material comprises at least one of silicon, metal, and ceramic.

15. The laminate of claim 14, wherein the metal is at least one of an aluminum alloy, stainless steel (SUS), titanium, and nickel, and the ceramic is at least one of aluminum oxide, aluminum nitride, silicon carbide, and silicon nitride.

16. The laminate of claim 11, wherein the base material has a thickness of 1 mm or more and 10 mm.

17. The laminate of claim 11, wherein a concentration of a component other than Al₂O₃ or Y₂O₃ in the amorphous layer is 5 at. % or less.

18. A laminate for a chamber inner wall of a semiconductor manufacturing apparatus, comprising:
a base material;
an amorphous layer on the base material; and
a crystalline layer on the amorphous layer,
wherein the amorphous layer comprises aluminum oxide or yttrium oxide,
wherein the crystalline layer is a YF₃ layer, and
wherein a concentration of a component other than yttrium and fluorine in the crystalline layer is 5 at. % or less.

19. The laminate of claim 18, wherein the base material comprises at least one of silicon, metal, and ceramic.

20. The laminate of claim 18, wherein a concentration of a component other than Al₂O₃ or Y₂O₃ in the amorphous layer is 5 at. % or less.
